(19) United States
(12) Patent Application Publication
(10) Pub. No.: US 2025/0277716 A1
(43) Pub. Date: Sep. 4, 2025

(54) SIMULATION METHOD AND SYSTEM FOR WIND TUNNEL SUBSTRUCTURE TEST OF ULTRA HIGH-RISE BUILDING

(71) Applicant: GUANGZHOU UNIVERSITY, Guangzhou (CN)

(72) Inventors: Huimeng ZHOU, Guangzhou (CN); Jiahui TANG, Guangzhou (CN); Jianwen ZHANG, Guangzhou (CN); Yuncheng HE, Guangzhou (CN); Yanhui LIU, Guangzhou (CN)

(73) Assignee: GUANGZHOU UNIVERSITY, Guangzhou (CN)

(21) Appl. No.: 18/959,264

(22) Filed: Nov. 25, 2024

(30) Foreign Application Priority Data
Feb. 29, 2024 (CN) 202410230630.1

(51) Int. Cl. G01M 9/02; G01M 5/00; G06F 30/13

(52) U.S. Cl. CPC G01M 9/02; G01M 5/00; G06F 30/13

(57) ABSTRACT

A test simulation method and system for wind tunnel substructure test of an ultra high-rise building is provided. The method comprises: taking it as a test substructure comprising a scale model that a wind tunnel test is performed on a critical part of a structure of the ultra high-rise building, and taking a numerical model of a non-critical part of the structure of the ultra high-rise building as a numerical substructure; calculating a model force of the scale model from the test substructure; and calculating an acceleration response at a node of a critical layer by a response solving algorithm, based on information on the obtained model force and numerical substructure. A situation is broken where a current wind tunnel test cannot build an effective model when a scale ratio is too small. By reducing the expense and process for making the model, it is economically applicable, simple, and convenient.

### CROSS-REFERENCE TO RELATED PATENT APPLICATIONS

This application claims a priority from the Chinese Patent Application No. 202410230630.1, filed with the Chinese Patent Office on Feb. 29, 2024, entitled “SIMULATION METHOD AND SYSTEM FOR WIND TUNNEL SUBSTRUCTURE TEST OF ULTRA HIGH-RISE BUILDING”, contents of which are incorporated herein by reference in its entirety.

### FIELD OF THE INVENTION

The invention relates to the technical field of simulation model, and in particular to a simulation method and a system for wind tunnel substructure test of an ultra high-rise building.

### BACKGROUND OF THE INVENTION

Although some countries have developed wind load calculation formulas for a high-rise building to determine a wind load at a design stage of a building structure, these formulas are only applicable to a building with a regular shape in a low-altitude area. For an ultra high-rise building with a large height or a complex shape, a wind tunnel test is often required to evaluate its structural response and change on equivalent static wind load. Traditional static analysis has difficulty in accurately simulating wind load characteristics of the ultra high-rise building, while numerical simulation cannot provide reliable data. Therefore, the wind tunnel test is a primary method for evaluating a wind effect.

At present, in the wind tunnel test of the ultra high-rise building, due to limitations of cost and size, a restoration effect of a critical part in the wind tunnel test may not be guaranteed because a scale ratio is too small.

### SUMMARY OF THE INVENTION

According to one or more embodiments of the present application, there is provided a simulation method for wind tunnel substructure test of an ultra high-rise building, including:
taking it as a test substructure that a wind tunnel test is performed on a critical part of a structure of the ultra high-rise building, and taking a numerical model of a non-critical part of the structure of the ultra high-rise building as a numerical substructure, wherein the test substructure comprises a scale model;
calculating a model force of the scale model from the test substructure; and
calculating an acceleration response at a node of a critical layer by a response solving algorithm, based on information on the obtained model force and the numerical substructure.

Further, the test substructure further comprises a wind tunnel device and a terminal device, wherein the scale model is connected with the terminal device.

Further, the calculating of a model force of the scale model from the test substructure comprises:
obtaining wind pressure data for a measurement point of the scale model by applying an incoming wind to the scale model via the wind tunnel device, transmitting the wind pressure data to the terminal device, and calculating the model force of the scale model via a force solving algorithm.

Further, the numerical substructure is established by:
utilizing stiffness, damping and mass data obtained from an in-situ test of the non-critical part of the structure of the ultra high-rise building.

Further, the scale model is a top mast of the ultra high-rise building.

Further, the model force is calculated by:
using a program of Matlab/Simulink in the terminal device, based on the wind pressure data for the measurement point obtained from the wind tunnel test performed on the scale model, to calculate in sequence a wind pressure coefficient, a measurement point surface wind pressure and a lateral force, and obtaining an approximately uniform load by linear interpolation.

Further, the calculating of an acceleration response at a node of a critical layer by a response solving algorithm based on information on the obtained model force and the numerical substructure comprises:
inputting the obtained model force into the numerical substructure, calculating an equivalent load based on the stiffness, damping and mass data contained in the numerical substructure, combining the equivalent load with an equivalent stiffness matrix to find a displacement at time i+1, and obtaining an acceleration at time i+1.

According to one or more embodiments of the present application, there is provided a simulation system for wind tunnel substructure test of an ultra high-rise building, comprising a test substructure and a numerical substructure, wherein the test substructure comprises a scale model and is used for performing a wind tunnel test on a critical part and calculating a model force of the scale model, and an acceleration response at a node of a critical layer is calculated based on the model force in combination with information provided by the numerical substructure.

According to one or more embodiments of the present application, there is provided an electronic device including:
a processor; and
a memory arranged to store a computer-executable instruction that, when executed, causes the processor to implement the steps of the above-described simulation method for wind tunnel substructure test of an ultra high-rise building.

According to one or more embodiments of the present application, there is provided a storage medium for storing a computer-executable instruction that, when executed, implements steps of the above-described simulation method for wind tunnel substructure test of an ultra high-rise building.

With the embodiment of the present application, a vibration replication test of an ultra high-rise building is performed by combining a wind tunnel test with a substructure simulation to examine the cause of abnormal vibration of the ultra high-rise building. The requirement for a scale model and loading equipment is reduced, and simulation of an ultra high-rise building vibration response can be performed within a wind tunnel. Thus, a situation is broken where a current wind tunnel test cannot build an effective model when a scale ratio is too small. By reducing the expense and process for making the model, it is economically applicable, simple, and convenient.

The foregoing description is merely a summary of the technical solution of the present application. In order that the technical means of the present application can be more clearly understood to be practiced in light of the description, and in order that the above and other objects, features and advantages of the present application can be more clearly understood, the specific embodiment of the present application is set forth as follows.

### BRIEF DESCRIPTION OF THE DRAWINGS

In order to illustrate more clearly one or more embodiments of the present application or technical solutions in the prior art, the drawings required for the description of the embodiments or of the prior art will now be briefly described. It will be apparent that the drawings in the following description are merely some of the embodiments described in this specification, and other drawings can be derived from these drawings without inventive labor for a person of ordinary skill in the art.

FIG. 1 is a flow chart of a simulation method for wind tunnel substructure test of an ultra high-rise building according to one or more embodiments of the present application;

FIG. 2 is a composition schematic diagram of a simulation system for wind tunnel substructure test of an ultra high-rise building according to one or more embodiments of the present application; and

FIG. 3 is a structural schematic diagram of an electronic device according to one or more embodiments of the present application.

### DETAILED DESCRIPTION OF THE INVENTION

In order to allow those skilled in the art to better understand the technical solutions in one or more embodiments of the present application, the technical solutions in one or more embodiments of the present application will be clearly and fully described below in connection with the accompanying drawings in one or more embodiments of the present specification. It will be apparent that the described embodiments are only some, but not all, embodiments of the present application. Based on one or more embodiments of the present application, all other embodiments obtained by those of ordinary skill in the art without creative labor fall within the scope of protection of the present application.

### Embodiments of Method

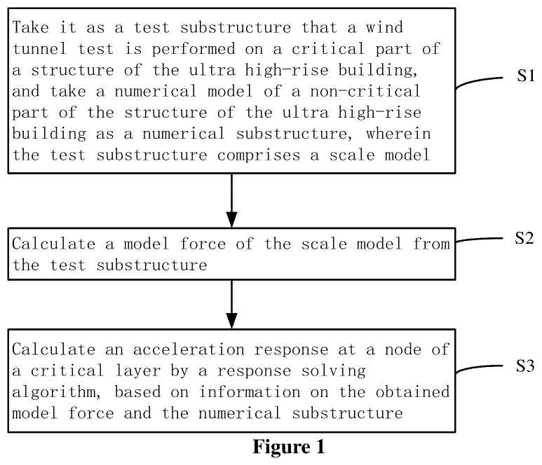

According to an embodiment of the present application, there is provided a simulation method for wind tunnel substructure test of an ultra high-rise building. FIG. 1 is a flow chart of a simulation method for wind tunnel substructure test of an ultra high-rise building according to one or more embodiments of the present application. As shown in FIG. 1, a simulation method for wind tunnel substructure test of an ultra high-rise building according to an embodiment of the present application specifically comprises the following steps.

S1. Take it as a test substructure that a wind tunnel test is performed on a critical part of a structure of the ultra high-rise building, and take a numerical model of a non-critical part of the structure of the ultra high-rise building as a numerical substructure, wherein the test substructure comprises a scale model.

Specifically, taking the wind field conditions close to the actual vibration as the standard, a simulation of vibration response of an ultra high-rise building is performed in a wind tunnel. According to the abnormal vibration of the ultra high-rise building, the critical part causing vibration is used as a scale model for a wind tunnel test. The result of the wind tunnel test is used for a test substructure, which comprises a wind tunnel device and a terminal device, and the scale model is connected with the terminal device.

The numerical substructure is established by:
utilizing stiffness, damping and mass data obtained from an in-situ test of the non-critical part of the structure of the ultra high-rise building.

In this embodiment, a top mast of the ultra high-rise building is used as the scale model for the wind tunnel test.

S2. Calculate a model force of the scale model from the test substructure.

In particular, wind pressure data for a measurement point of the scale model is obtained by applying an incoming wind to the scale model via a wind tunnel device, the wind pressure data is transmitted to the terminal device, and the model force of the scale model is calculated via a force solving algorithm.

The modeled force is the shear force at the bottom of the mast, and the vibration critical layer is 69, corresponding to the 44th node of the numerical substructure. The model force is calculated by:
using a program of Matlab/Simulink in the terminal device, based on the wind pressure data for the measurement point obtained from the wind tunnel test performed on the scale model, to calculate in sequence a wind pressure coefficient, a measurement point surface wind pressure and a lateral force, and obtaining an approximately uniform load by linear interpolation.

S3. Calculate an acceleration response at a node of a critical layer by a response solving algorithm, based on information on the obtained model force and the numerical substructure.

Specifically, the obtained model force is inputted into the numerical substructure, an equivalent load is calculated based on the stiffness, damping and mass data contained in the numerical substructure, the equivalent load is combined with an equivalent stiffness matrix to find a displacement at time i+1, and an acceleration at time i+1 is obtained.

The beneficial effects of the present application are as follows.

With the embodiment of the present application, an vibration replication test of an ultra high-rise building is performed by combining a wind tunnel test with a substructure simulation to examine the cause of abnormal vibration of the ultra high-rise building. The requirement for a scale model and loading equipment is reduced, and simulation of an ultra high-rise building vibration responses can be performed within a wind tunnel. Thus, a situation is broken where a current wind tunnel test cannot build an effective model when a scale ratio is too small. By reducing the expense and process for making the model, it is economically applicable, simple, and convenient.

### Embodiments of System

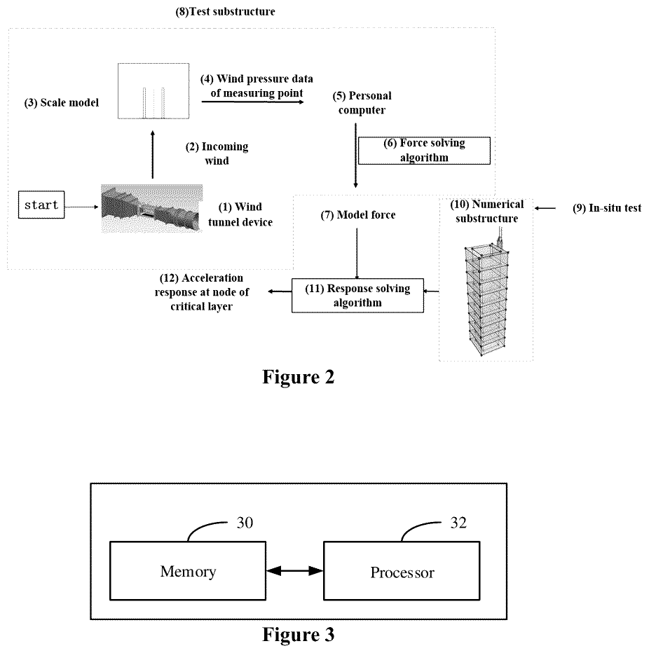

According to an embodiment of the present application, there is provided a simulation system for wind tunnel substructure test of an ultra high-rise building. FIG. 2 is a composition schematic diagram of a simulation system for wind tunnel substructure test of an ultra high-rise building according to one or more embodiments of the present application. As shown in FIG. 2, a simulation system for wind tunnel substructure test of an ultra high-rise building according to an embodiment of the present application specifically comprises a test substructure 8 and a numerical substructure 10.

The test substructure 8 comprises a scale model 3 and is used for performing a wind tunnel test on a critical part and calculating a model force 7 of the scale model 3. An acceleration response 12 at a node of a critical layer is calculated based on the model force 7 in combination with information provided by the numerical substructure 10.

In particular, wind pressure data 4 for a measurement point of the scale model 3 is obtained by applying an incoming wind 2 to the scale model 3 via the wind tunnel device 1, the wind pressure data 4 is transmitted to the terminal device, which is a personal computer 5 in this embodiment, and the model force of the scale model is calculated via a force solving algorithm 6.

Stiffness, damping and mass data obtained from an in-situ test 9 of a non-critical part of the structure of the ultra high-rise building are utilized to establish the numerical substructure 10.

The acceleration response 12 at the node of the critical layer is calculated by a response solving algorithm 11 based on information on the obtained model force 7 and the numerical substructure 10.

Embodiments of the present application are embodiments of the system corresponding to the embodiments of the method described above, and the specific operation of the various modules can be understood by reference to the description of the method embodiments and will not be repeated here.

### First Embodiment of Device

According to an embodiment of the present application, there is provided an electronic device, as shown in FIG. 3, comprising a memory 30, a processor 32 and a computer program stored on the memory 30 and executable on the processor 32. The computer program, when executed by the processor 32, implements the following steps.

S1. Take it as a test substructure that a wind tunnel test is performed on a critical part of a structure of the ultra high-rise building, and take a numerical model of a non-critical part of the structure of the ultra high-rise building as a numerical substructure, wherein the test substructure comprises a scale model.

S2. Calculate a model force of the scale model from the test substructure.

S3. Calculate an acceleration response at a node of a critical layer by a response solving algorithm, based on information on the obtained model force and the numerical substructure.

### Second Embodiment of Device

According to an embodiment of the present application, there is provided a computer readable storage medium on which an implementation program for information transmission is stored, and the following steps are implemented when the program is executed by a processor 32.

S1. Take it as a test substructure that a wind tunnel test is performed on a critical part of a structure of the ultra high-rise building, and take a numerical model of a non-critical part of the structure of the ultra high-rise building as a numerical substructure, wherein the test substructure comprises a scale model.

S2. Calculate a model force of the scale model from the test substructure.

S3. Calculate an acceleration response at a node of a critical layer by a response solving algorithm, based on information on the obtained model force and the numerical substructure.

The computer-readable storage media described herein include, but are not limited to, ROM, RAM, magnetic or optical disks, and the like.

Finally, it should be noted that the above embodiments are only used to illustrate the technical solution of the present application, not to limit it. Although the present application has been described in detail with reference to the foregoing embodiments, it will be understood by those skilled in the art that the technical solutions described in the foregoing embodiments may be modified or equivalents may be substituted for some or all of the technical features thereof. Such modifications or substitutions do not make the essence of the corresponding technical solutions depart from the scope of the technical solutions of the embodiments of the present application.

1. A simulation method for wind tunnel substructure test of an ultra high-rise building, comprising:
taking it as a test substructure that a wind tunnel test is performed on a critical part of a structure of the ultra high-rise building, and taking a numerical model of a non-critical part of the structure of the ultra high-rise building as a numerical substructure, wherein the test substructure comprises a scale model;
calculating a model force of the scale model from the test substructure; and
calculating an acceleration response at a node of a critical layer by a response solving algorithm, based on information on the obtained model force and the numerical substructure.

2. The simulation method according to claim 1, wherein the test substructure further comprises a wind tunnel device and a terminal device, wherein the scale model is connected with the terminal device.

3. The simulation method according to claim 2, wherein the calculating of a model force of the scale model from the test substructure comprises:
obtaining wind pressure data for a measurement point of the scale model by applying an incoming wind to the scale model via the wind tunnel device, transmitting the wind pressure data to the terminal device, and calculating the model force of the scale model via a force solving algorithm.

4. The simulation method according to claim 2, wherein the numerical substructure is established by:
utilizing stiffness, damping and mass data obtained from an in-situ test of the non-critical part of the structure of the ultra high-rise building.

5. The simulation method according to claim 1, wherein the scale model is a top mast of the ultra high-rise building.

6. The simulation method according to claim 2, wherein the model force is calculated by:
using a program of Matlab/Simulink in the terminal device, based on the wind pressure data for the measurement point obtained from the wind tunnel test performed on the scale model, to calculate in sequence a wind pressure coefficient, a measurement point surface wind pressure and a lateral force, and obtaining an approximately uniform load by linear interpolation.

7. The simulation method according to claim 4, wherein the calculating of an acceleration response at a node of a critical layer by a response solving algorithm based on information on the obtained model force and the numerical substructure comprises:
inputting the obtained model force into the numerical substructure, calculating an equivalent load based on the stiffness, damping and mass data contained in the numerical substructure, combining the equivalent load with an equivalent stiffness matrix to find a displacement at time i+1, and obtaining an acceleration at time i+1.

8. A simulation system for wind tunnel substructure test of an ultra high-rise building, comprising a test substructure and a numerical substructure, wherein the test substructure comprises a scale model and is used for performing a wind tunnel test on a critical part and calculating a model force of the scale model, and an acceleration response at a node of a critical layer is calculated based on the model force in combination with information provided by the numerical substructure.

9. An electronic device, comprising:
a processor; and
a memory arranged to store a computer-executable instruction that, when executed, causes the processor to implement the steps of the simulation method for wind tunnel substructure test of an ultra high-rise building according to claim 1.

10. A storage medium for store a computer-executable instruction that, when executed, implements the steps of the simulation method for wind tunnel substructure test of an ultra high-rise building according to claim 1.
